(19) United States
(12) Patent Application Publication
(10) Pub. No.: US 2024/0266466 A1
(43) Pub. Date: Aug. 8, 2024

(54) DISPLAY PANEL AND PREPARATION METHOD THEREFOR, AND DISPLAY DEVICE

(71) Applicants: Beijing BOE Display Technology Co., Ltd., Beijing (CN); BOE Technology Group Co., Ltd., Beijing (CN)

(72) Inventors: Chuanxiang XU, Beijing (CN); Shi SHU, Beijing (CN); Guangcai YUAN, Beijing (CN); Qi YAO, Beijing (CN)

(21) Appl. No.: 18/638,431

(22) Filed: Apr. 17, 2024

Related U.S. Application Data
(63) Continuation of application No. PCT/CN2022/128390, filed on Oct. 28, 2022.

(51) Int. Cl. H01L 33/20; H01L 25/075; H01L 25/16; H01L 33/62

(52) U.S. Cl. CPC H01L 33/20; H01L 25/0753; H01L 25/167; H01L 33/62; H01L 2933/0066

(57) ABSTRACT

A display panel, a preparation method therefor, and a display device. The display panel includes: a stretchable substrate including: island areas in array, bridge areas, blanking areas outside the island areas and the bridge areas; the bridge area connects two adjacent island areas; a flexible substrate on one side of stretchable substrate, the flexible substrate includes: a hollow area corresponding to bridge and blanking areas; a driving circuit layer on one side away from stretchable substrate, of the flexible substrate; the driving circuit layer includes: drive units and connecting leads; the drive units are in island areas, the connecting lead passes through the bridge area and extends to the island area to be electrically connected with the drive unit; in unstretched state, at least parts of the connecting lead sinks on one side facing the flexible substrate or the connecting lead protrudes on one side away from the flexible substrate.

### CROSS-REFERENCE TO RELATED APPLICATIONS

This disclosure is a continuation of International Application No. PCT/CN2022/128390, filed on Oct. 28, 2022, which is hereby incorporated by reference in its entirety.

### TECHNICAL FIELD

The present disclosure relates to the field of display technology, and in particular, relates to a display panel and a preparation method therefor, and a display device.

### BACKGROUND

With the development of the flexible process, there is a gradual transition from bending, buckling, and to elastic flexibility. A flexible stretchable display has received extensive attention from the market due to its broad application space. In the existing technology, a flexible stretchable display product requires openings in the flexible substrate to form an island-bridge structure, with light emitting devices and the like placed in the island area, and connecting wires placed in the bridge area, to achieve the stretching function of the display panel. However, the stretch rate of the flexible substrate is low, and signal lines in the bridge area are disposed on the flexible substrate, which affects the stretch rate of the display product.

### SUMMARY

An embodiment of the present disclosure provides a display panel, including:
a stretchable substrate, including: a plurality of island areas arranged in an array, a plurality of bridge areas, and blanking areas outside the island areas and the bridge areas; wherein the bridge area connects two adjacent island areas;
a flexible substrate on one side of the stretchable substrate, wherein the flexible substrate includes: a hollow area corresponding to the bridge area and the blanking area; and
a driving circuit layer on one side, away from the stretchable substrate, of the flexible substrate; wherein the driving circuit layer includes: a plurality of drive units and a plurality of connecting leads; the drive units are located in the island areas, and the connecting lead passes through the bridge area and extends to the island area to be electrically connected with the drive unit; and in an unstretched state of the stretchable substrate, at least a portion of the connecting lead sinks on one side facing the flexible substrate or the connecting lead protrudes on one side away from the flexible substrate.

In some embodiments, the connecting lead has at least one protrusion on the side facing the flexible substrate and/or on the side away from the flexible substrate.

In some embodiments, the connecting lead has a plurality of protrusions; and the plurality of protrusions are not oriented in exactly the same direction.

In some embodiments, an extended profile of the protrusion has a plurality of sub-protrusions; and the plurality of sub-protrusions are oriented in the same direction.

In some embodiments, a shape of an orthographic projection of the connecting lead on the bridge area is curved.

In some embodiments, the drive unit includes: a thin film transistor; the connecting lead is located on one side, away from the flexible substrate, of the thin film transistor; the driving circuit layer further includes: a first protective layer between the connecting lead and the thin film transistor, a second protective layer between the first protective layer and the connecting lead, and a third protective layer on one side, away from the flexible substrate, of the connecting lead; the second protective layer and the third protective layer pass through the bridge area and extend to the island area; an orthographic projection of the connecting lead on the flexible substrate falls within an orthographic projection of the second protective layer on the flexible substrate, and the orthographic projection of the connecting lead on the flexible substrate falls within an orthographic projection of the third protective layer on the flexible substrate; and the third protective layer covers a surface on the side, away from the flexible substrate, of the connecting lead, and a side surface of the connecting lead.

In some embodiments, in the bridge area, the orthographic projection of the second protective layer on the flexible substrate approximately coincides with the orthographic projection of the third protective layer on the flexible substrate.

In some embodiments, the connecting lead includes: a first sub-layer, and a second sub-layer on one side, away from the flexible substrate, of the first sub-layer; and in a direction perpendicular to the flexible substrate, a thickness of the second sub-layer is greater than a thickness of the first sub-layer.

In some embodiments, the display panel further includes: a plurality of micro-sized inorganic light emitting diode devices, which are located in the island area and bound to the driving circuit layer on one side, away from the flexible substrate, of the driving circuit layer; and a stretchable cover plate on one side, away from the flexible substrate, of the micro-sized inorganic light emitting diode devices.

An embodiment of the present disclosure provides a method for preparing a display panel, including:
providing a first substrate; wherein the first substrate includes: a plurality of island areas arranged in an array, a plurality of bridge areas, and blanking areas outside the island areas and the bridge areas; and the bridge area connects two adjacent the island areas;
forming a flexible substrate on one side of the first substrate;
forming a pattern of a driving circuit layer on one side, away from the first substrate, of the flexible substrate, and patterning the flexible substrate to form hollow areas in the blanking areas and the bridge areas; wherein the driving circuit layer includes: a plurality of drive units and a plurality of connecting leads; the drive units are located in the island areas, and the connecting lead passes through the bridge area and extends to the island area to be electrically connected with the drive unit;
stripping the first substrate and transferring a structure formed on one side of the first substrate to a stretchable substrate that is stretched by applying a tension force; and
releasing the tension force on the stretchable substrate to cause the stretchable substrate to restore to an unstretched state; wherein, in the unstretched state of the stretchable substrate, at least a portion of the connecting lead sinks on one side facing the flexible substrate or the connecting lead protrudes on one side away from the flexible substrate.

In some embodiments, an operation of forming the pattern of the driving circuit layer on one side, away from the first substrate, of the flexible substrate, and patterning the flexible substrate to form the hollow areas in the blanking areas and the bridge areas, specifically includes:
forming a pattern of a partial film layer included in the driving circuit layer on the side, away from the first substrate, of the flexible substrate, and patterning the flexible substrate to form the hollow areas in the blanking areas and the bridge areas;
forming a sacrificial layer in an area corresponding to the hollow area;
forming a pattern of the connecting lead on one side, away from the first substrate, of the sacrificial layer; and
removing the sacrificial layer.

In some embodiments, the forming the sacrificial layer in the area corresponding to the hollow area, specifically includes: forming a metal sacrificial layer in the area corresponding to the hollow area by using an electroplating process;
the removing the sacrificial layer, specifically includes: removing the sacrificial layer by using a wet etching process.

In some embodiments, the forming the metal sacrificial layer in the area corresponding to the hollow area by using the electroplating process, specifically includes:
forming a seed layer covering the partial film layer and the hollow area;
forming a strippable electroplating retaining wall covering the seed layer in an area outside the hollow area;
powering on the seed layer to grow an electroplating layer in the hollow area, and filling the area corresponding to the hollow area to form the metal sacrificial layer;
removing the strippable electroplating retaining wall; and
removing the seed layer outside the hollow area and thinning the metal sacrificial layer, to make a surface on one side, away from the first substrate, of the metal sacrificial layer be in approximately the same plane as a surface on one side, away from the first substrate, of the partial film layer.

In some embodiments, the forming the sacrificial layer in the area corresponding to the hollow area, specifically includes: forming an organic sacrificial layer by filling the area corresponding to the hollow area with an organic material;
the removing the sacrificial layer, specifically includes: removing the organic sacrificial layer by using a stripping process with a stripping solution.

In some embodiments, after forming the sacrificial layer in the area corresponding to the hollow area, and before forming the pattern of the connecting lead on one side, away from the first substrate, of the sacrificial layer, the method further includes: forming a plurality of spacer structures on the side, away from the first substrate, of the sacrificial layer; wherein the plurality of spacer structures are arranged at intervals in an arrangement direction of two adjacent island areas; and a surface on one side, away from the first substrate, of the spacer structure is curved;
while removing the sacrificial layer, the method further includes: removing a spacer layer.

In some embodiments, an operation of forming the pattern of the partial film layer included in the driving circuit layer on the side, away from the first substrate, of the flexible substrate, and patterning the flexible substrate to form the hollow areas in the blanking areas and the bridge areas, specifically includes: forming a pattern of film layers of a thin film transistor on the side, away from the first substrate, of the flexible substrate; wherein the pattern of the film layers of the thin film transistor does not overlap with the blanking area and the bridge area; forming a pattern of a first protective layer on one side, away from the first substrate, of the film layers of the thin film transistor; wherein the pattern of the first protective layer does not overlap with the blanking area and the bridge area; and patterning the flexible substrate by using the pattern of the first protective layer as a mask, to form the hollow areas in the blanking areas and the bridge areas;
before forming the pattern of the connecting lead on the side, away from the first substrate, of the sacrificial layer, the method further includes: forming a pattern of a second protective layer on the side, away from the first substrate, of the sacrificial layer; wherein the second protective layer passes through the bridge area and extends to the island area;
after forming the pattern of the connecting lead on the side, away from the first substrate, of the sacrificial layer, the method further includes: forming a pattern of a third protective layer on one side, away from the sacrificial layer, of the connecting lead; wherein the third protective layer passes through the bridge area and extends to the island area.

In some embodiments, after removing the sacrificial layer and before stripping the first substrate, the method further includes: binding a micro-sized inorganic light emitting diode device on one side, away from the flexible substrate, of the driving circuit layer; and affixing a protective film on one side, away from the flexible substrate, of the micro-sized inorganic light emitting diode device;
after releasing the tension force on the stretchable substrate to cause the stretchable substrate returns to restore to the unstretched state, the method further includes: removing the protective film.

In some embodiments, after removing the protective film, the method further includes: affixing a stretchable cover on one side, away from the flexible substrate, of the micro-sized inorganic light emitting diode device.

A display device provided by an embodiment of the present disclosure includes the display panel provided by the embodiments of the present disclosure.

### BRIEF DESCRIPTION OF FIGURES

In order to more clearly illustrate the technical solutions in the embodiments of the present disclosure, the accompanying drawings required in the description of the embodiments will be briefly described below. Obviously, the accompanying drawings in the following description are only some embodiments of the present disclosure, and other accompanying drawings can be obtained according to these drawings for those of ordinary skill in the field without making creative labour.

FIG. 1 shows a schematic structural diagram of a display panel provided by embodiments of the present disclosure.

FIG. 2 shows another schematic structural diagram of a display panel provided by embodiments of the present disclosure.

FIG. 3 shows yet another schematic structural diagram of a display panel provided by embodiments of the present disclosure.

FIG. 4 shows yet another schematic structural diagram of a display panel provided by embodiments of the present disclosure.

FIG. 5 shows yet another schematic structural diagram of a display panel provided by embodiments of the present disclosure.

FIG. 6 shows yet another schematic structural diagram of a display panel provided by embodiments of the present disclosure.

FIG. 7 shows yet another schematic structural diagram of a display panel provided by embodiments of the present disclosure.

FIG. 8 shows yet another schematic structural diagram of a display panel provided by embodiments of the present disclosure.

FIG. 9 shows yet another schematic structural diagram of a display panel provided by embodiments of the present disclosure.

FIG. 10 shows yet another schematic structural diagram of a display panel provided by embodiments of the present disclosure.

FIG. 11 shows yet another schematic structural diagram of a display panel provided by embodiments of the present disclosure.

FIG. 12 shows yet another schematic structural diagram of a display panel provided by embodiments of the present disclosure.

FIG. 13 shows a flow chart of a preparation method of a display panel provided by embodiments of the present disclosure.

FIG. 14A shows a schematic structural diagram of a display panel corresponding a certain step of a preparation method of the display panel provided by embodiments of the present disclosure.

FIG. 14B shows a schematic structural diagram of a display panel corresponding a certain step of a preparation method of the display panel provided by embodiments of the present disclosure.

FIG. 14C shows a schematic structural diagram of a display panel corresponding a certain step of a preparation method of the display panel provided by embodiments of the present disclosure.

FIG. 14D shows a schematic structural diagram of a display panel corresponding a certain step of a preparation method of the display panel provided by embodiments of the present disclosure.

FIG. 14E shows a schematic structural diagram of a display panel corresponding a certain step of a preparation method of the display panel provided by embodiments of the present disclosure.

FIG. 14F shows a schematic structural diagram of a display panel corresponding a certain step of a preparation method of the display panel provided by embodiments of the present disclosure.

FIG. 15 shows a schematic diagram of a cross-sectional structure of a bridge area and a blanking area provided by embodiments of the present disclosure.

FIG. 16 shows a schematic diagram of forming a spacer structure in a preparation method of a display panel provided by embodiments of the present disclosure.

FIG. 17 shows a schematic diagram of forming a recess in a preparation method of a display panel provided by embodiments of the present disclosure.

FIG. 18 shows a schematic diagram of forming a sacrificial layer in a preparation method of a display panel provided by embodiments of the present disclosure.

### DETAILED DESCRIPTION

In order to make the purpose, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are some embodiments of the present disclosure, rather than all of the embodiments. And the embodiments and the features in the embodiments of the present disclosure can be combined with each other without conflict. Based on the described embodiments of the present disclosure, all other embodiments obtained by a person of ordinary skill in the art without the need for creative labour fall within the scope of protection of the present disclosure.

Unless otherwise defined, technical or scientific terms used in the present disclosure shall have the ordinary meaning understood by a person of ordinary skill in the art to which the present disclosure belongs. The words such as “first”, “second” used in the present disclosure do not indicate any order, number, or importance, but are used only to distinguish different components. The words such as “including” or “comprising” are intended to mean that the component or object that appears before the word includes the components or objects listed after the word and their equivalents, and does not exclude other components or objects. Words such as “connected” or “connecting” are not limited to physical or mechanical connections, but may include electrical connections, whether direct or indirect.

It should be noted that the sizes and shapes of the figures in the accompanying drawings do not reflect true proportions, but are intended to illustrate the content of the present disclosure. And throughout the same or similar reference numerals indicate the same or similar elements or elements having the same or similar function.

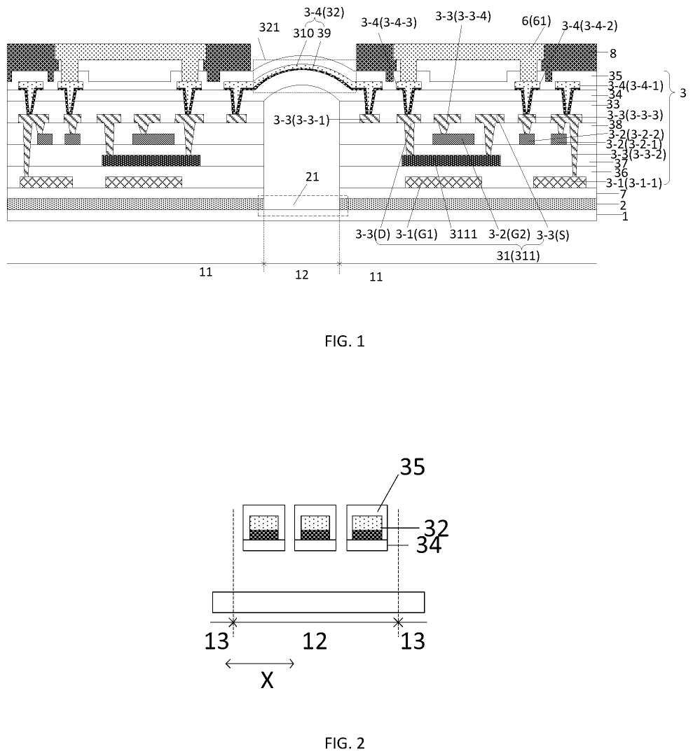

Embodiments of the present disclosure provide a display panel, as shown in FIG. 1. The display panel includes:
a stretchable substrate 1, including a plurality of island areas 11 arranged in an array, a plurality of bridge areas 12, and blanking areas 13 outside the island areas 11 and the bridge areas 12; each bridge area 12 connects two adjacent island areas 11;
a flexible substrate 2, located on one side of the stretchable substrate 1, and including a hollow area 21 corresponding to the bridge area 12 and the blanking area 13; and
a driving circuit layer 3, located on one side, away from the stretchable substrate 1, of the flexible substrate; the driving circuit layer 3 including: a plurality of drive units 31 and a plurality of connecting leads 32; the drive units 31 are located in the island areas 11, and the connecting lead 32 passes through the bridge area 12 and extend to the island area 11 to be electrically connected with the drive unit 31; and in an unstretched state of the stretchable substrate 1, at least a portion of the connecting lead 32 sinks on one side facing the flexible substrate or the connecting lead protrudes on one side away from the flexible substrate.

The display panel provided in the embodiments of the present disclosure, the flexible substrate in the bridge area is removed and the connecting lead passing through the bridge area is suspended, which can avoid the low stretch rate of the flexible substrate from affecting the overall stretching performance of the display panel. Moreover, a stretchable substrate is provided on the side, away from the driving circuit layer, of the flexible substrate. In an stretched state of the stretchable substrate, the flexible substrate and each film layer on one side of the flexible substrate are transferred to the stretchable substrate, and afterwards, the stretchable substrate is restored to the unstretched state, which may reduce the size of the bridge area, so that at least a portion of the connecting lead sinks on one side facing the flexible substrate or the connecting lead protrudes on one side away from the flexible substrate, that is, the connecting lead is in a bent state. In this way, in the process that the display panel is stretched, the connecting lead is stretched from the bent state to the straight extension state, which improves the stretch rate of the display panel compared to stretching the connecting lead from the straight extension state.

In some embodiments, as shown in FIG. 1, the drive unit 31 includes: a thin film transistor 311;
the connecting lead 32 is located on one side, away from the flexible substrate 2, of the thin film transistor 311;
the driving circuit layer 3 further includes: a first protective layer 33 between the connecting lead 32 and the thin film transistor 311, a second protective layer 34 between the first protective layer 33 and the connecting lead 32, and a third protective layer 35 located on one side, away from the flexible substrate 2, of the connecting lead 32;
the second protective layer 34 and the third protective layer 35 pass through the bridge area 12, extend to the island area 11, and cover at least a portion of the island area 11;
an orthographic projection of the connecting lead 32 on the flexible substrate 2 falls within an orthographic projection of the second protective layer 34 on the flexible substrate 2, and an orthographic projection of the connecting lead 32 falls within an orthographic projection of the third protective layer 35 on the flexible substrate 2; and
the third protective layer 35 covers a surface on the side, away from the flexible substrate 2, of the connecting lead 32, and a side surface of the connecting lead 32.

In the display panel provided by embodiments of the present disclosure, the second protective layer and the third protective layer pass through the bridge area from the island area, the orthographic projection of the connecting lead falls with the orthographic projection of the second protective layer in the bridge area, and the third protective layer covers the connecting lead, so that the upper and lower surfaces of the connecting lead that passes through the bridge area are protected even if the connecting lead is in the unsupported suspended state, to avoid damage to the connecting lead that passes through the bridge area.

In some embodiments, as shown in FIG. 2, in the bridge area 12, a width of the second protective layer 34 in the X direction is greater than a width of the connecting lead 32 in the X direction, and a width of the third protective layer 35 in the X direction is greater than the width of the connecting lead 32 in the X direction.

In some embodiments, as shown in FIG. 2, in the bridge area 12, the orthographic projection of the second protective layer 34 on the flexible substrate 2 approximately coincides with the orthographic projection of the third protective layer 35 on the flexible substrate 2.

It is to be noted that the approximate coincidence between the orthographic projection of the second protective layer on the flexible substrate and the orthographic projection of the third protective layer on the flexible substrate means that, in the X direction, the distance difference between the edge of the second protective layer and the edge of the third protective layer is less than the allowable range of the process error, which can be regarded as, the orthographic projection of the second protective layer on the flexible substrate and the orthographic projection of the third protective layer on the flexible substrate coincide.

It should be noted that in FIG. 2, three connecting leads passing through the bridge area are taken as an example for illustration, and in specific implementation, the number of connecting leads passing through the bridge area needs to be set according to the specific structure of the drive unit.

In some embodiments, as shown in FIG. 1, the display panel further includes:
a plurality of light emitting devices 6 in the island area which are located on one side, away from the flexible substrate 2, of the driving circuit layer 3.

In some embodiments, as shown in FIG. 1, the light emitting device 6 is a micro-sized inorganic light emitting diode device 61, and the micro-sized inorganic light emitting diode device 61 is located in the island area and bound to the driving circuit layer 3 on one side, away from the flexible substrate 2, of the driving circuit layer 3.

In specific implementation, the micro-sized inorganic light emitting diode is, for example, a mini light emitting diode (Mini-LED) or a micro light emitting diode (Micro-LED). The mini-LED and micro-LED have a small size and the high brightness, and can be widely used in display devices or backlight modules of the display devices. For example, a typical size (e.g., length) of the Micro-LED is less than 100 microns, such as 10 microns to 80 microns; and a typical size (e.g., length) of the Mini-LED ranges from 80 microns to 350 microns, such as 80 microns to 120 microns.

Of course, in specific implementation, the light emitting device may also be an organic light emitting diode device.

In specific implementation, as shown in FIG. 1, the display panel further includes a silicon-based filler layer 8 located on one side, away from the flexible substrate 2, of the driving circuit layer 3.

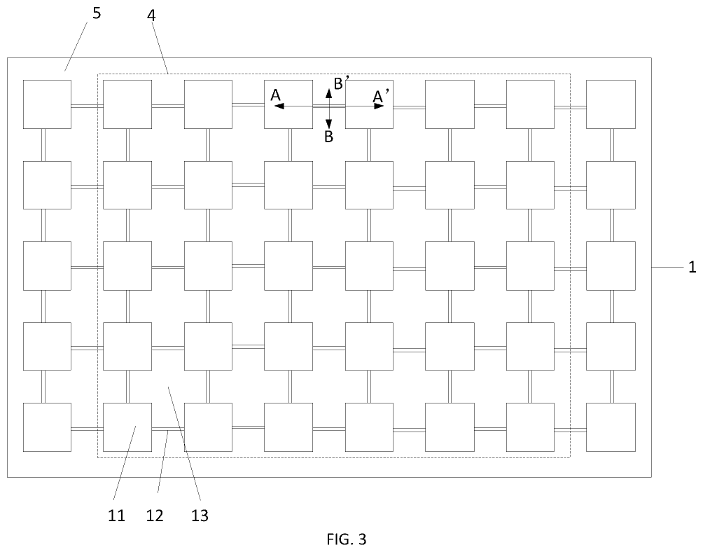

It is to be noted that, in a specific embodiment, as shown in FIG. 3, the display panel includes a display area 4 and a peripheral area 5 surrounding the display area 4, and the stretchable substrate 1 of both the display area 4 and the peripheral area 5 includes an island area 11, a bridge area 12, and a blanking area 13. In the display area 4, the drive unit is a display drive unit, and the display drive unit includes, for example, a thin film transistor and a capacitor; and the island area 11 includes a plurality of pixels (not shown), each pixel includes a plurality of sub-pixels, and each sub-pixel includes one display driver unit. In the peripheral area 5, the drive unit is a peripheral drive unit. For example, the periphery includes a gate driving circuit, the gate driving circuit includes a plurality of cascaded peripheral drive units, the peripheral drive units may also include thin film transistors and capacitors, and the peripheral drive units may be disposed on at least one island area 11 of the peripheral area. FIG. 1 maybe, for example, a cross-sectional view along the line AA′ in FIG. 3, and FIG. 2 maybe, for example, a cross-sectional view along the line BB′ in FIG. 3. The drive unit illustrated in FIG. 1 is a display drive unit.

In specific implementation, as shown in FIG. 1, the display panel further includes a buffer layer 7 between the driving circuit layer 3 and the flexible substrate 2. The driving circuit layer specifically includes: a first conductive layer 3-1, a first gate insulating layer 36, an active layer 3111, a second gate insulating layer 37, a second conductive layer 3-2, an interlayer insulating layer 38 and a third conductive layer 3-3 which are disposed in sequence between the buffer layer 7 and the first protective layer 33; and a fourth conductive layer 3-4 between the second protective layer 34 and the third protective layer 35. Here, the first conductive layer 3-1 includes: a first gate G1 of the thin film transistor 311, and a first connecting portion 3-1-1; the second conductive layer 3-2 includes: a second gate G2 of the thin film transistor 311, a second connecting portion 3-2-1, and a third connecting portion 3-2-2; the third conductive layer 3-3 includes: a source S and a drain D of the thin film transistor 311, a fourth connecting portion 3-3-1 which is electrically connected to the connecting lead 32, a fifth connecting portion 3-3-2, a sixth connecting portion 3-3-3, and a seventh connecting portion 3-3-4; and the fourth conductive layer 3-4 includes: the connecting lead 32, an eighth connecting portion 3-4-1, a ninth connecting portion 3-4-2, and a tenth connecting portion 3-4-3. That is, the thin film transistors of the embodiments in the disclosure are thin film transistors of a double-gate structure. Of course, the thin film transistors may also be thin film transistors of other structures such as a top gate, a bottom gate, and the like.

In specific implementation, as shown in FIG. 1, the connecting lead 32 is electrically connected to the fourth connecting portion 3-3-1 through a through-hole penetrating the second protective layer 34 and the first protective layer 33, and the fourth connecting portion 3-3-1 is electrically connected to the drive unit 31 (no specific connection is shown), thereby achieving electrical connection between the connecting lead 32 and the drive unit 31. The tenth connecting portion 3-4-3 is electrically connected to the drain D through the through-hole penetrating the second protective layer 34 and the first protective layer 33, the third protective layer 35 exposes a part of the tenth connecting portion 3-4-3, and one of binding ends of the micro-sized inorganic light emitting diode device 61 is bound to the tenth connecting portion 3-4-3. The ninth connecting portion 3-4-2 is electrically connected to the sixth connecting portion 3-3-3 through the through-hole penetrating the second protective layer 34 and the first protective layer 33, the sixth connecting portion 3-3-3 is electrically connected to the third connecting portion 3-2-2 through a through-hole penetrating the interlayer insulating layer 38, the third protective layer 35 exposes a part of the ninth connecting portion 3-4-2, and one of the binding ends of the micro-sized inorganic light emitting diode device 61 is electrically connected to the ninth connecting portion 3-4-2. In specific implementation, for example, a low-level power supply signal (VSS) may be provided to the micro-sized inorganic light emitting diode device 61 through the third connecting portion 3-2-2, the sixth connecting portion 3-3-3, and the ninth connecting portion 3-4-2. The eighth connecting portion 3-4-1 is electrically connected to the fifth connecting portion 3-3-2 through the through-hole penetrating the second protective layer 34 and the first protective layer 33, the fifth connecting portion 3-3-2 is electrically connected to the second connecting portion 3-2-1 through the through-hole penetrating the interlayer insulating layer 38, and the fifth connecting portion 3-3-2 is electrically connected to the first connecting portion 3-1-1 through a through-hole penetrating the interlayer insulating layer 38, the second gate insulating layer 37, and the first gate insulating layer 36. In specific implementation, a high-level power supply signal (VDD) may be provided to the drive unit through the eighth connecting portion 3-4-1, the fifth connecting portion 3-3-2, the second connecting portion 3-2-1, and the first connecting portion 3-1-1.

In specific implementation, as shown in FIG. 1, the fourth conductive layer 3-4 includes a first sub-layer 39 and a second sub-layer 310 on one side, away from the flexible substrate 2, of the first sub-layer 39. That is, the connecting lead 32 includes the first sub-layer 39 and the second sub-layer 310.

In some embodiments, in a direction perpendicular to the flexible substrate, the fourth conductive layer has a thickness greater than or equal to 0.05 microns and less than or equal to 15 microns.

Therefore, the fourth conductive layer is thicker, i.e., the connecting lead is thicker, which may reduce the resistance of the connecting lead and also prevent the connecting lead in the bridge area from breaking when stretched.

In specific implementation, in the direction perpendicular to the flexible substrate, the thickness of the fourth conductive layer is preferably greater than or equal to 1 micron and less than or equal to 10 microns.

In specific implementation, in FIG. 1, the fourth conductive layer 3-4 is formed by using an electroplating process, the first sub-layer 39 serves as a seed layer for the electroplating process, and a second sub-layer 310 is grown on the seed layer. The second sub-layer includes at least one element same as the first sub-layer. For example, both the first sub-layer and the second sub-layer include copper. In the direction perpendicular to the flexible substrate, a thickness of the second sub-layer 310 is greater than a thickness of the first sub-layer 39 in FIG. 1.

The display panel provided by embodiments of the present disclosure uses an electroplating process to form the thicker fourth conductive layer, which is simple and easy to implement.

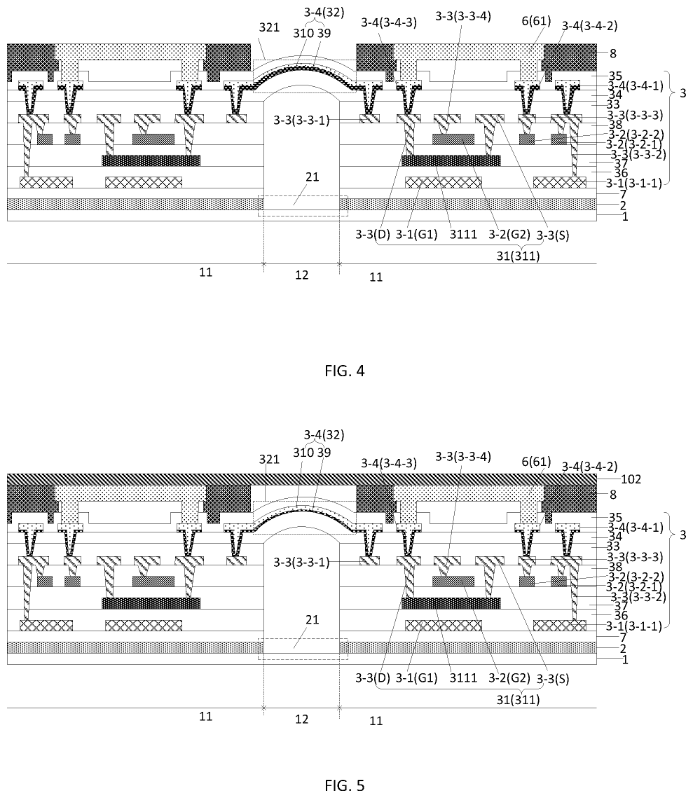

Of course, a deposition process may also be used to form the fourth conductive layer. For example, a first sub-layer may be deposited first, and then a second sub-layer is deposited. For example, as shown in FIG. 4, in the direction perpendicular to the flexible substrate and in an area outside the through-hole, the first sub-layer 39 has the same thickness as the second sub-layer 310. In this way, the thickness of the deposited first sub-layer and second sub-layer can be avoided to be too thick, reducing the difficulty of forming the fourth conductive layer by the deposition process.

Of course, the thicknesses of the first sub-layer and the thicknesses of the second sub-layer formed by the deposition process may not be the same.

In specific implementation, the deposition process is used to form the fourth conductive layer, and the first sub-layer and the second sub-layer include the same material or different materials.

In some embodiments, as shown in FIG. 5, the display panel further includes:
a stretchable cover 102 located on one side, away from the flexible substrate 2, of the micro-sized inorganic light emitting diode devices 6.

In the display panel provided in the embodiments of the present disclosure, the cover plate covering the micro-sized inorganic light emitting diode devices is a stretchable cover plate, so as to avoid the cover plate from affecting the stretching effect of the display panel, and improve a stretch rate of the display panel.

In specific implementation, the material of the flexible substrate may be, for example, polyimide (PI); the material of the active layer may be, for example, the low-temperature polycrystalline silicon or oxide semiconductor; and the first protective layer, the second protective layer and the third protective layer may be either an organic protective layer or an inorganic protective layer, or may also be a stack of the organic protective layer and the inorganic protective layer.

In some embodiments, as shown in FIG. 1 and FIGS. 6-11, the connecting lead 32 has at least one protrusion 321 on one side facing the flexible substrate 2 and/or on one side away from the flexible substrate 2.

It is noted that after transferring the film layers provided on the flexible substrate to the stretchable substrate to which the tension force is applied, the applied tension force is cancelled to cause the stretchable substrate to restore to an unstretched state, which can reduce the size of the bridge area, such that the connecting lead is in a bent state, and the connecting lead in the bent state has at least one protrusion on the side facing the flexible substrate and/or on the side away from the flexible substrate.

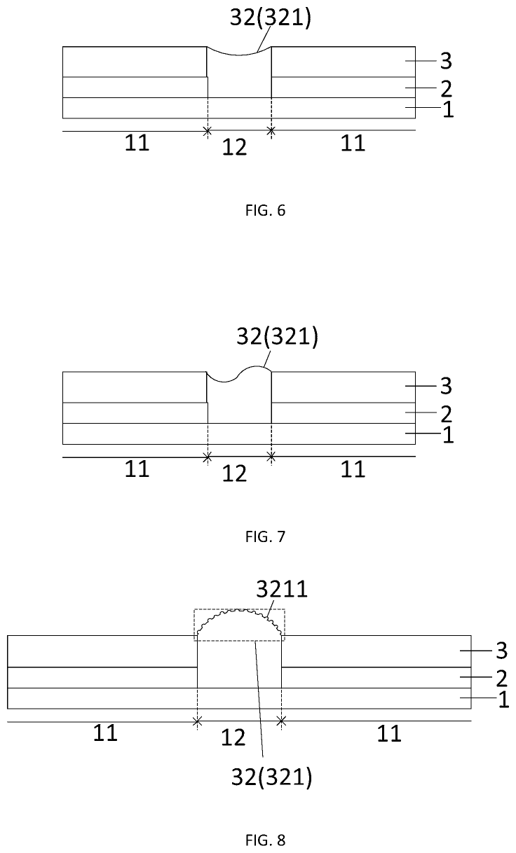

In some embodiments, as shown in FIGS. 1 and 6, the connecting lead 32 has one protrusion 321, on one side facing the flexible substrate 2 or on one side away from the flexible substrate 2. Here, the protrusion 321 is on one side away from the flexible substrate 2 in FIG. 1, and the protrusion 321 is on the side facing the flexible substrate 2 in FIG. 6.

In some embodiments, the connecting lead 32 has a plurality of protrusions 321 as shown in FIG. 7 to FIG. 11.

In some embodiments, as shown in FIG. 7, the plurality of protrusions 321 are not oriented in exactly the same direction. It is to be noted that the plurality of protrusions being not oriented in exactly the same direction means that: some of the plurality of protrusions protrude on the side facing the flexible substrate, and the rest of the plurality of protrusions protrude on the side away from the flexible substrate. As shown in FIG. 7, the connecting lead 32 has a protrusion 321 on the side facing the flexible substrate 2 and a protrusion 321 on the side away from the flexible substrate 2.

It should be noted that FIG. 7 illustrates the connecting lead 32 having two protrusions 321 as an example. In specific implementation, the connecting lead may also have more protrusions.

In specific embodiments, after transferring the flexible substrate and the film layers above the flexible substrate to the stretchable substrate, the applied tension force is cancelled to cause the stretchable substrate to restore to an unstretched state, so that the connecting lead sinks on one side facing the flexible substrate or the connecting lead protrudes on one side away from the flexible substrate. Therefore, the connecting lead has one protrusion 321 as shown in FIG. 6 or a plurality of protrusions 321 as shown in FIG. 7.

In some embodiments, as shown in FIG. 8 to FIG. 11, an extended profile of the protrusion 321 has a plurality of sub-protrusions 3211, and the plurality of sub-protrusions 3211 are oriented in the same orientation. It should be noted that, the plurality of sub-projections 3211 being oriented in the same orientation means that: all of the plurality of sub-projections 3211 protrude on one side away from the flexible substrate 2, or all of the plurality of sub-projections 3211 protrude on one side facing the flexible substrate 2.

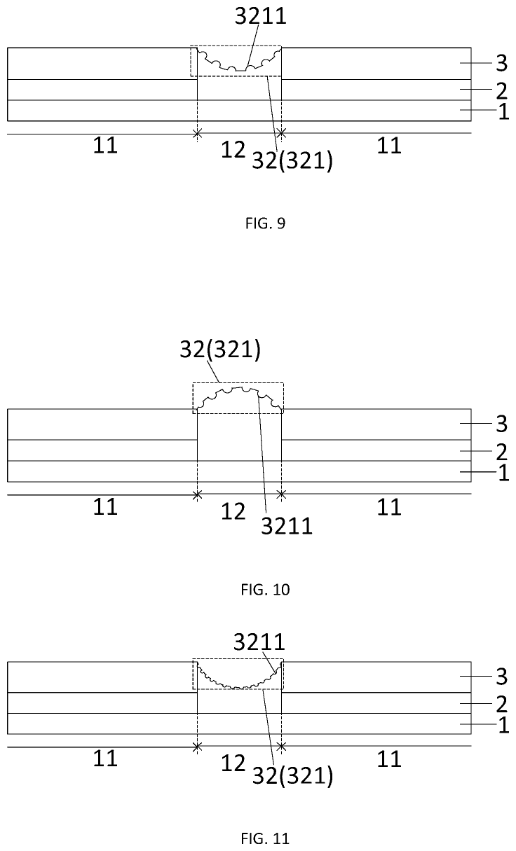

Here, the connecting lead 32 includes a protrusion 321 on one side facing the flexible substrate 2, as shown in FIG. 9 and FIG. 11; and the connecting lead 32 includes a protrusion 321 on one side away from the flexible substrate 2, as shown in FIG. 8 and FIG. 10.

The extended profile of the protrusion 321 of the connecting lead 32 has a plurality of sub-protrusions 3211 on the side away from the flexible substrate 2, as shown in FIGS. 8-9; and the extended profile of the protrusion 321 of the connecting lead 32 has a plurality of sub-protrusions 3211 on the side facing the flexible substrate 2, as shown in FIGS. 10-11.

It should be noted that if the connecting lead includes a plurality of protrusions, for example, all sub-projections included in the plurality of protrusions are oriented in the same direction, thereby simplifying the difficulty of preparing the sub-protrusions.

In specific implementation, in the process of preparing the connecting lead, the plurality of protrusions on the side away from the flexible substrate or the plurality of protrusions on the side facing the flexible substrate may be formed first, to increase the extension length of the connecting lead, thereby increasing the stretch rate of the connecting lead. Moreover, after transferring the flexible substrate and the film layers above the flexible substrate to the stretchable substrate, the applied tensile force is cancelled to cause the stretchable substrate to restore to an unstretched state, so that the connecting lead having the plurality of protrusions further sinks on the side facing the flexible substrate or protrudes on the side away from the flexible substrate, which may further improve the stretch rate of the connecting leads, thereby improving the stretchable performance of the display panel.

In some embodiments, as shown in FIG. 3, the bridge area is bar-shaped. The shape of an orthographic projection of the connecting lead on the bridge area is rectilinear.

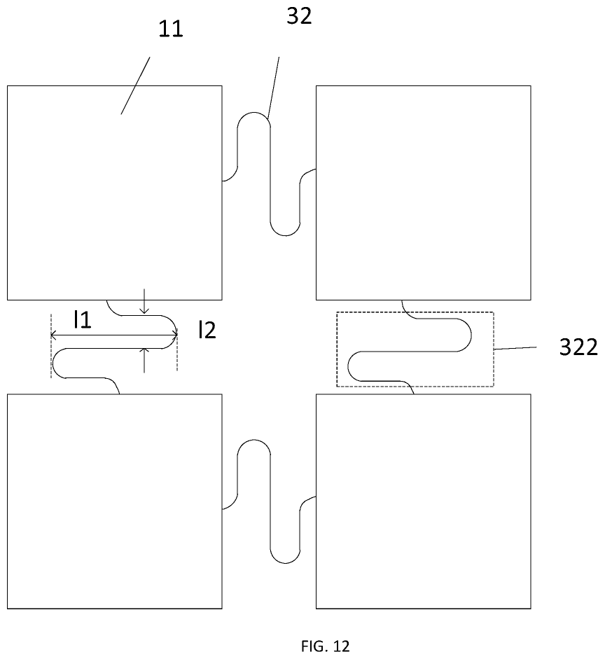

Alternatively, in some embodiments, as shown in FIG. 12, the shape of the orthographic projection of the connecting lead 32 on the bridge area 12 is curved.

In the display panel provided by embodiments of the present disclosure, the shape of the orthographic projection of the connecting lead on the bridge area is curved instead of rectilinear, which can further increase the extension length of the connecting lead, thereby increasing the stretch rate of the connecting lead, and improving the stretchable performance of the display panel.

It is to be noted that FIG. 12 illustrates an example that the curved shape of the orthographic projection of the connecting lead 32 on the bridge area 12 has a set of bending units 322 for illustration. Of course, in specific implementation, the curved shape of the orthographic projection of the connecting lead 32 on the bridge area 12 may also include multiple sets of bending units 322. For example, the curved shape of the orthographic projection of the connecting lead on the bridge area may include 1 to 12 sets of bending units. In specific implementation, as shown in FIG. 12, the bending unit 322 has a first width I1 and a second width I2, the first width I1 is a width of the bending unit 322 in a direction perpendicular to an arrangement direction of the two island areas 11, and the second width I2 is a width of the bending unit 322 in the arrangement direction of the two island areas 11. For example, I1:I2 is greater than or equal to 1:2 and less than or equal to 10:1. Of course, it is also possible to choose the first width I1 to be greater than the second width I2, that is, I1:I2 is, for example, greater than or equal to 1:1 and less than or equal to 10:1.

In specific implementation, regardless of the number of protrusions the connecting lead has, the shape of the orthographic projection of the connecting lead on the bridge area may be set to be curved. When the connecting lead has a plurality of protrusions facing the same direction, the connecting lead sinks on the side facing the flexible substrate or protrudes on the side away from the flexible substrate, and the shape of the orthographic projection of the connecting lead on the bridge area is curved, which can increase the extension length of the connecting lead both in the direction perpendicular to the flexible substrate and in the direction parallel to the flexible substrate, to increase the stretchable performance of the display panel as much as possible.

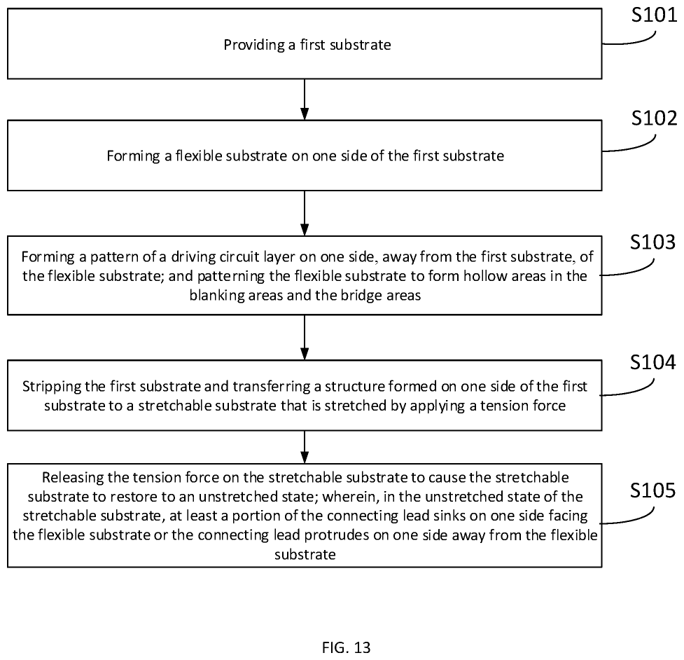

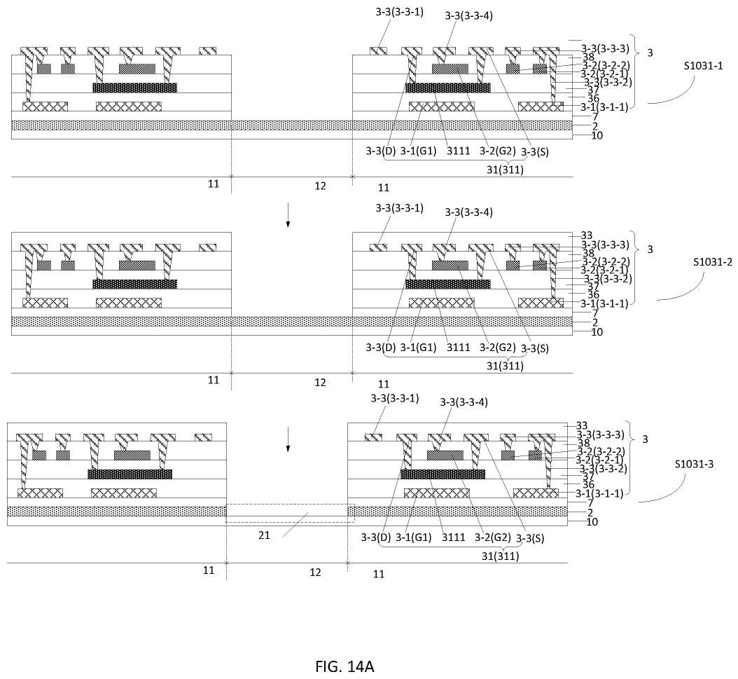

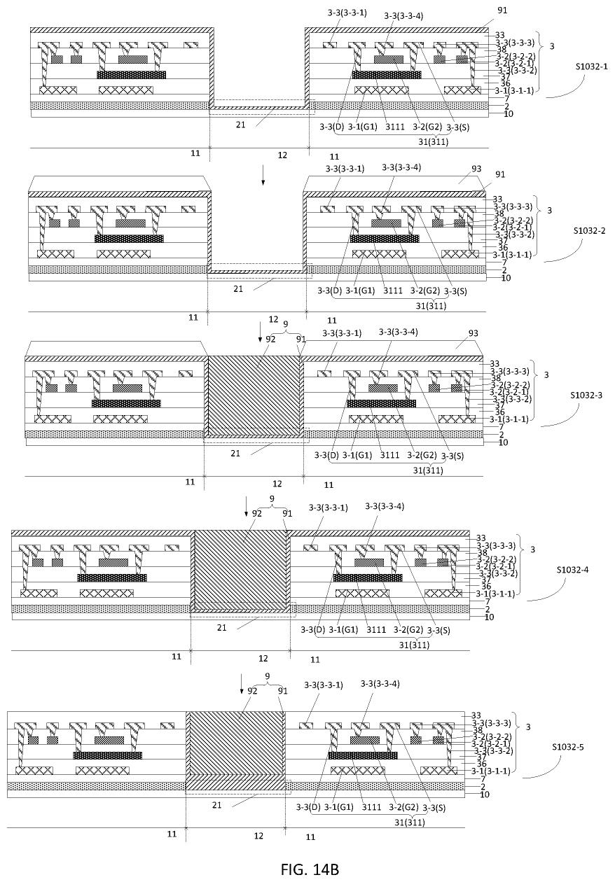

Based on the same inventive concept, embodiments of the present disclosure also provide a method of preparing a display panel, as shown in FIG. 13, including:
S101, providing a first substrate; wherein the first substrate includes: a plurality of island areas arranged in an array, a plurality of bridge areas, and blank areas outside the island areas and the bridge areas; and the bridge area connects two adjacent island areas;
S102, forming a flexible substrate on one side of the first substrate;
S103, forming a pattern of a driving circuit layer on one side, away from the first substrate, of the flexible substrate; and patterning the flexible substrate to form hollow areas in the blanking areas and the bridge areas; wherein the driving circuit layer includes: a plurality of drive units and a plurality of connecting leads; the drive units are located in the island areas, and the connecting lead passes through the bridge area and extend to the island area to be electrically connected with the drive unit;
S104, stripping the first substrate and transferring a structure formed on one side of the first substrate to a stretchable substrate that is stretched by applying a tension force; and
S105, releasing the tension force on the stretchable substrate to cause the stretchable substrate to restore to an unstretched state; wherein, in the unstretched state of the stretchable substrate, at least a portion of the connecting lead sinks on one side facing the flexible substrate or the connecting lead protrudes on one side away from the flexible substrate.

In the method of preparing a display panel provided in embodiments of the present disclosure, the flexible substrate in the bridge area is removed and the connecting lead passing through the bridge area is suspended, which can avoid the low stretch rate of the flexible substrate from affecting the overall stretching performance of the display panel. Moreover, the film layers located on the flexible substrate are transferred to the stretchable substrate to which the tension force is applied, and afterwards, the stretchable substrate is restored to the unstretched state, which may reduce the size of the bridge area, so that at least a portion of the connecting lead sinks on one side facing the flexible substrate or the connecting lead protrudes on one side away from the flexible substrate, that is, the connecting lead is in a bent state. In this way, in the process that the display panel is stretched, the connecting lead is stretched from the bent state to the straight extension state, which improves the stretch rate of the display panel compared to stretching the connecting lead from the straight extension state.

In specific implementation, for example, a buckling induction process may be used to transfer a structure formed on one side of the first substrate to a stretchable substrate that is stretched by applying a tension force.

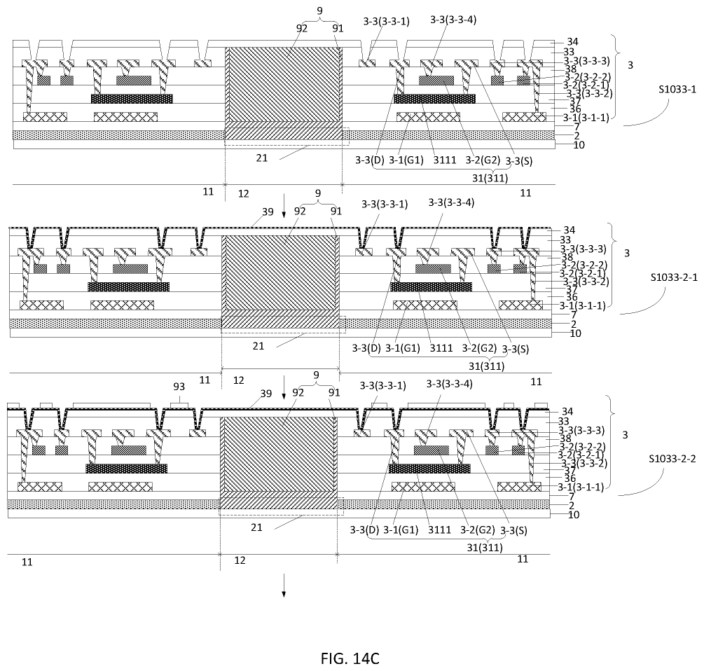

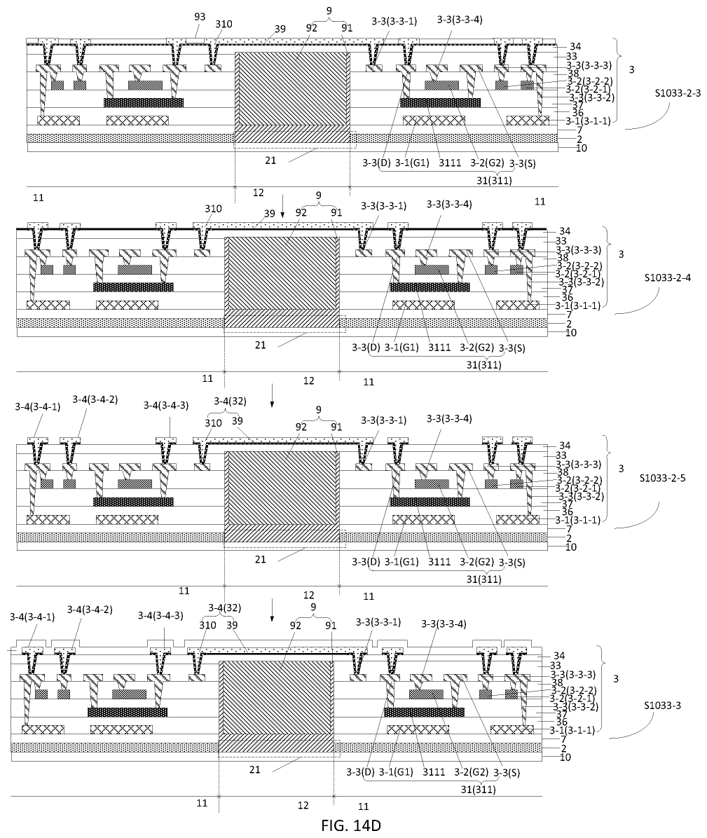

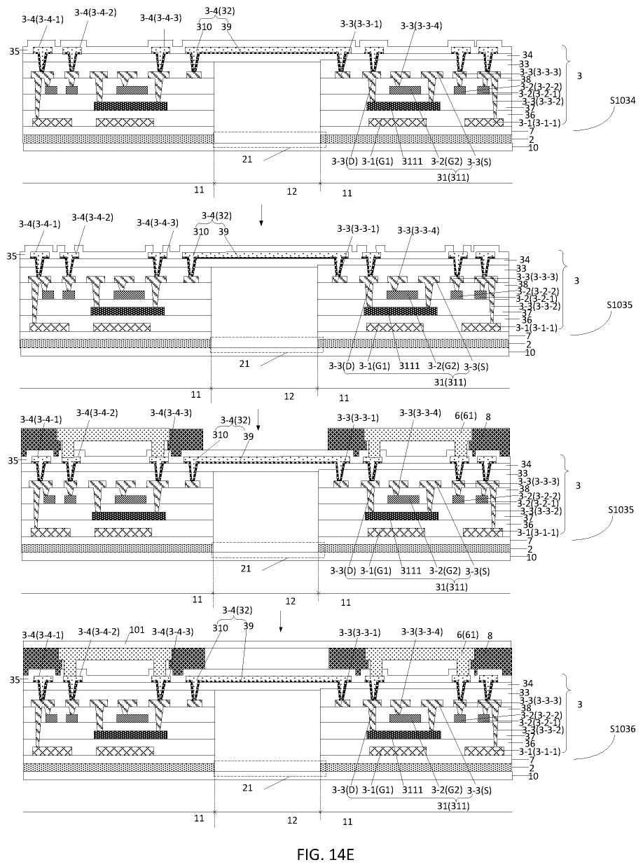

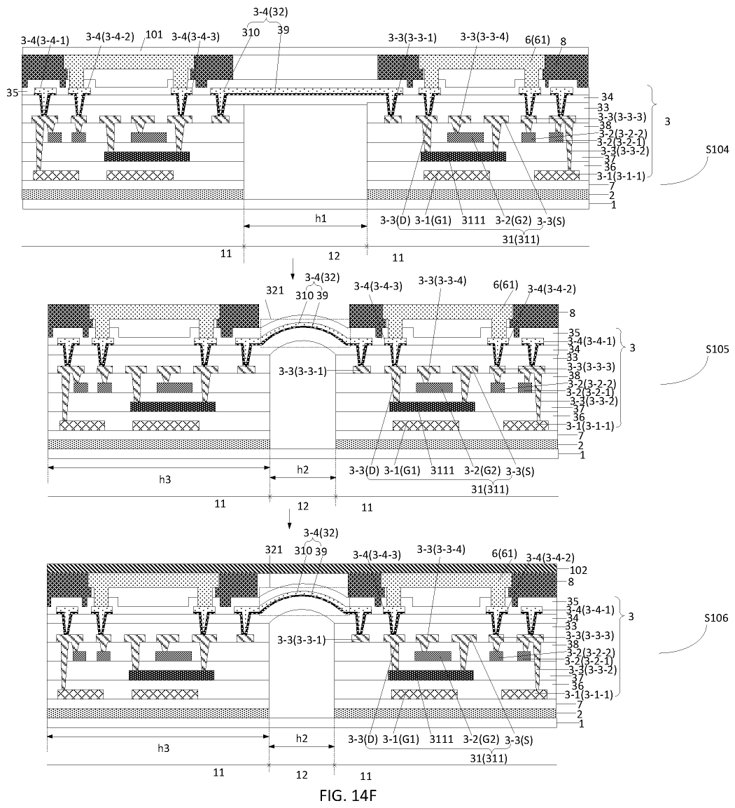

In some embodiments, as shown in FIG. 14A to FIG. 14E, the step S103 of forming the pattern of the driving circuit layer 3 on the side, away from the first substrate, of the flexible substrate 2, and patterning the flexible substrate 2 to form the hollow areas 21 in the blanking areas 13 and the bridge areas 12, specifically includes:
S1031, forming a pattern of a partial film layer included in the driving circuit layer 3 on the side, away from the first substrate 10, of the flexible substrate 2, and patterning the flexible substrate 2 to form the hollow areas 21 in the blanking areas 13 and the bridge areas 12;
S1032, forming a sacrificial layer 9 in an area corresponding to the hollow area 21;
S1033, forming a pattern of the connecting lead 32 on one side, away from the first substrate 10, of the sacrificial layer 9; and
S1034, removing the sacrificial layer 9.

In some embodiments, as shown in FIG. 14B, the step S1032 of forming the sacrificial layer 9 in the area corresponding to the hollow area 21, specifically includes:
forming a metal sacrificial layer 9 in the area corresponding to the hollow area 21 by using an electroplating process.

When the sacrificial layer is a metal sacrificial layer, in some embodiments, removing the sacrificial layer, specifically includes: removing the sacrificial layer by using a wet etching process.

In some embodiments, as shown in FIG. 14B, forming the metal sacrificial layer by using the electroplating process in the area corresponding to the hollow area 21, specifically includes:
S1032-1, forming a seed layer 91 covering the partial film layer of the driving circuit layer 3 and the hollow area 21;
S1032-2, forming a strippable electroplating retaining wall 93 covering the seed layer in the area outside the hollow area 21;
S1032-3, powering on the seed layer 91 to grow an electroplating layer 92 in the hollow area 21, and filling the area corresponding to the hollow area 21 to form the metal sacrificial layer 9;
S1032-4, removing the strippable electroplating retaining wall 93; and
S1032-5, removing the seed layer 91 outside the hollow area 21 and thinning the metal sacrificial layer 9, to make a surface on one side, away from the first substrate 10, of the metal sacrificial layer 9 be in approximately the same plane as a surface on one side, away from the first substrate 10, of the partial film layer of the driving circuit layer 3.

It is to be noted that, since the strippable electroplating retaining wall covering the seed layer is formed in the area outside the hollow area, the seed layer is electroplated by loading a voltage, the electroplating layer grows only in the area outside the electroplating retaining wall, i.e., only in the hollow area, and the electroplating time can be controlled so that the electroplating layer can fill the area corresponding to the hollow area.

In specific implementation, the etching time can be adjusted to thin the metal sacrificial layer, so that the surface on the side, away from the first substrate, of the metal sacrificial layer is in approximately the same plane as the surface on the side, away from the first substrate, of the partial film layer of the driving circuit layer.

It is to be noted that when the distance between the surface on the side, away from the first substrate, of the metal sacrificial layer, and the surface on the side, away from the first substrate, of the partial film layer of the driving circuit layer is less than a preset value, it can be regarded that the surface on the side, away from the first substrate, of the metal sacrificial layer is in the same plane as the surface on the side, away from the first substrate, of the partial film layer of the driving circuit layer.

In some embodiments, as shown in FIG. 14A, the step S1031 of forming the pattern of the partial film layer included in the driving circuit layer 3 on the side, away from the first substrate, of the flexible substrate 2, and patterning the flexible substrate 2 to form the hollow areas 21 in the blanking areas 13 and the bridge areas 12, specifically includes:
S1031-1, forming a pattern of film layers of a thin film transistor 311 on the side, away from the first substrate 10, of the flexible substrate 2; wherein the pattern of the film layers of the thin film transistor 311 does not overlap with the blanking area 13 and the bridge area 12;
S1031-2, forming a pattern of a first protective layer 33 on one side, away from the first substrate 10, of the film layers of the thin film transistor 311; wherein the pattern of the first protective layer 33 does not overlap with the blanking area 13 and the bridge area 12; and
S1031-3, patterning the flexible substrate 2 by using the pattern of the first protective layer 33 as a mask, to form the hollow areas 21 in the blanking areas 13 and the bridge areas 12.

As shown in FIG. 14C and FIG. 14D, the step S1033 of forming the pattern of the connecting lead 32 on the side, away from the first substrate 10, of the sacrificial layer 9, specifically includes:
S1033-1, forming a pattern of a second protective layer 34 on the side, away from the first substrate 10, of the sacrificial layer 9; wherein the second protective layer 34 passes through the bridge area 12 and extends to the island area 11;
S1033-2, forming the pattern of the connecting lead 32 on one side, away from the first substrate 10, of the second protective layer 34; and
S1033-3, forming a third protective layer 35 on one side, away from the sacrificial layer 9, of the connecting lead 32; wherein the third protective layer 35 passes through the bridge area 12 and extends to the island area 11.

In some embodiments, as shown in FIG. 14C and FIG. 14D, the step S1033-2 of forming the pattern of the connecting lead 32 on the side, away from the first substrate 10, of the second protective layer 34, specifically includes:
S1033-2-1, forming a first sub-layer 39 as an electroplating seed layer on one side, away from the first substrate 10, of the second protective layer 34;
S1033-2-2, forming a pattern of the strippable electroplating retaining wall 93 covering a port of the first sub-layer 39;
S1033-2-3, powering on the first sub-layer 39 to grow a second sub-layer 310 in an area which is not covered by the pattern of the strippable electroplating retaining wall 93;
S1033-2-4, removing the strippable electroplating retaining wall 93; and
S1033-2-5, removing the first sub-layer 39 in the area where the second sub-layer 310 is not grown, to form a pattern of a fourth conductive layer 3-4 including the connecting lead 32.

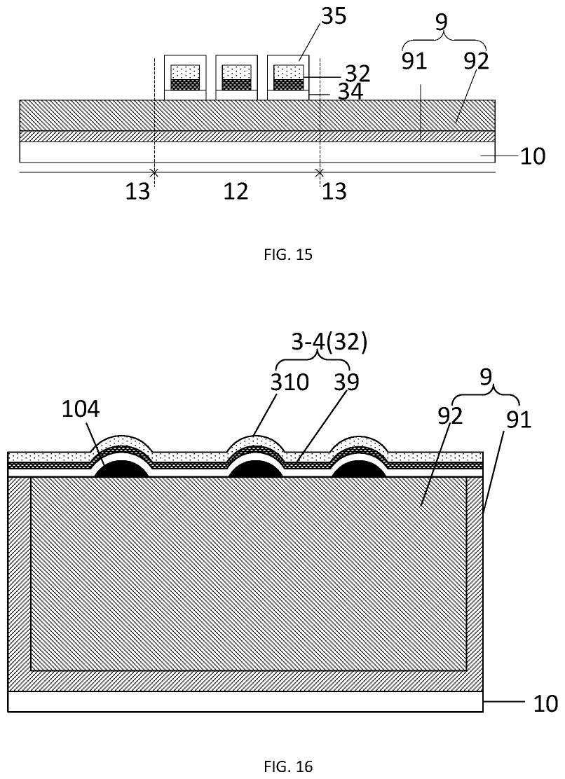

It is to be noted that a cross-section view of the bridge area and the blank area in the arrangement direction of the connecting leads is shown in FIG. 15.

It is to be noted that FIG. 14C and FIG. 14D are illustrated by way of example of forming the fourth conductive layer by an electroplating process. Alternatively, in some embodiments, the step S1033-2 of forming the pattern of the connecting lead on the side, away from the first substrate 10, of the second protective layer, specifically includes:
depositing a first sub-layer and a second sub-layer in sequence on the side, away from the first substrate, of the second protective layer; and
patterning the second sub-layer and the first sub-layer to form the pattern of the fourth conductive layer.

In some embodiments, as shown in FIG. 14E, after forming the third protective layer 35 on the side, away from the sacrificial layer 9, of the connecting lead 32, the method specifically includes:
S1034, removing the sacrificial layer 9; and
S1035, patterning the third protective layer 35 to form a pattern of the third protective layer 35, and expose a part of the fourth conductive layer 3-4.

In some embodiments, as shown in FIG. 14A, forming the pattern of the film layers of the thin film transistor 311 on the side, away from the first substrate 10, of the flexible substrate 2, specifically includes:
sequentially forming patterns of the buffer layer 7, the first conductive layer 3-1, the first gate insulating layer 36, the active layer 3111, the second gate insulating layer 37, the second conductive layer 3-2, the interlayer insulating layer 38, and the third conductive layer 3-3 on the side, away from the first substrate 10, of the flexible substrate 2.

In some embodiments, as shown in FIG. 14E, after removing the sacrificial layer and before stripping the first substrate, the method further includes:
S1036, binding a micro-sized inorganic light emitting diode device 61 on one side, away from the flexible substrate 2, of the driving circuit layer 3, and filling silica gel 8; and
S1037, affixing a protective film 101 on one side, away from the flexible substrate 2, of the micro-sized inorganic light emitting diode device 61.

In specific implementation, in the step S104, the first substrate is stripped, and by the buckling induction process, the structure formed on one side of the first substrate is transferred to the stretchable substrate that is stretched by applying the tension force; and in the step S105, the tension force of the stretchable substrate is released, so that the stretchable substrate is restored to an unstretched state; wherein, in the unstretched state of the stretchable substrate, the connecting lead is in a bent state as shown in FIG. 14F. Here, in the step S104, a width of the bridge area 12 is h1, and in the S105, after releasing the tension force of the stretchable substrate, the width of the bridge area 12 is h2. The width of the island area is h3. For example, h1:h3 is in the range of 1:5 to 5:1, and h1-h2 is less than a total thickness of the display panel in a direction perpendicular to the stretchable substrate.

In some embodiments, after releasing the tension force on the stretchable substrate to cause the stretchable substrate to restore to the unstretched state, the method further includes: removing the protective film.

In some embodiments, as shown in FIG. 14F, after removing the protective film, the method further includes:
S106, affixing a stretchable cover 102 on one side, away from the flexible substrate 2, of the micro-sized inorganic light emitting diode device 6.

In some embodiments, as shown in FIG. 16, after forming the sacrificial layer 9 in the area corresponding to the hollow area 21, and before forming the pattern of the connecting the lead 32 on the side, away from the first substrate 10, of the sacrificial layer 9, the method further includes:
forming a plurality of spacer structures 104 on the side, away from the first substrate 10, of the sacrificial layer 9; wherein the plurality of spacer structures 104 are arranged at intervals in an arrangement direction of two adjacent island areas 11; and a surface on one side, away from the first substrate 10, of the spacer structure 104 is curved.

In specific implementation, in the direction perpendicular to the first substrate, a maximum thickness of the spacer structure is greater than a thickness of the connecting lead and less than a thickness of the micro-sized inorganic light emitting diode device; and in the arrangement direction of the plurality of spacer structures, a width of the spacer structure is greater than the thickness of the connecting lead in the direction perpendicular to the first substrate.

In some embodiments, while removing the sacrificial layer, the method further includes: removing a spacer layer.

In the method for preparing a display panel provided in embodiments of the present disclosure, a plurality of spacer structures are formed on one side, away from the first substrate, of the sacrificial layer; and then a second protective layer, a connecting lead and a third protective layer are formed, such that the formed connecting lead is provided with a plurality of sub-protrusions on one side away from the flexible substrate, which can increase the length of the connecting lead, thereby increasing the stretch rate of the display panel.

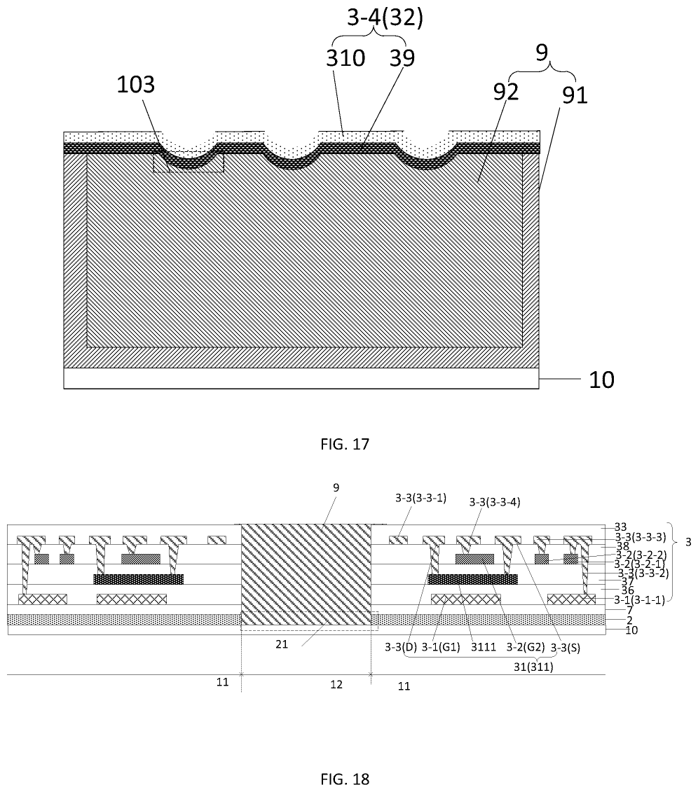

In some embodiments, as shown in FIG. 17, after forming the sacrificial layer 9 in the area corresponding to the hollow area 21, and before forming the pattern of the connecting lead 32 on the side, away from the first substrate 10, of the sacrificial layer 9, the method further includes:
forming a plurality of recesses 103 on the side, away from the first substrate 10, of the sacrificial layer 9; wherein the plurality of recesses 103 are arranged at intervals in an arrangement direction of two adjacent island areas 11; and a surface on one side, facing the first substrate 10, of the recess 103 is curved.

In the method for preparing a display panel provided in embodiments of the present disclosure, a plurality of recesses are formed on one side, away from the first substrate, of the sacrificial layer; and then a second protective layer, a connecting lead and a third protective layer are formed, such that the formed connecting lead is provided with a plurality of sub-protrusions on one side facing the flexible substrate, which can increase the length of the connecting lead, thereby increasing the stretch rate of the display panel.

In specific implementation, in the direction perpendicular to the first substrate, a maximum thickness of the recess is greater than the thickness of the connecting lead and less than a maximum thickness of the sacrificial layer; and in an arrangement direction of the plurality of recesses, a width of the recess is greater than the thickness of the connecting lead in the direction perpendicular to the first substrate.

It should be noted that FIG. 14A to FIG. 14D are illustrated by way of example of forming the sacrificial layer including a metal material by an electroplating process. Of course, the sacrificial layer may also include an organic material.

In some embodiments, as shown in FIG. 18, forming the sacrificial layer in the area corresponding to the hollow area 21, specifically includes:
forming an organic sacrificial layer 9 by filling the area corresponding to the hollow area 21 with an organic material.

In specific implementation, the organic material is, for example, a phenolic resin, a polyimide resin, and the like.

In some embodiments, removing the sacrificial layer, specifically includes: removing the organic sacrificial layer by using a stripping process with a stripping solution.

It should be noted that when the sacrificial layer is an organic sacrificial layer, the process of forming a second protective layer, a connecting lead, and a third protective layer on the organic sacrificial layer is the same as the process of forming the sacrificial layer including a metal material, and the process of preparing the display panel after removing the organic sacrificial layer is the same as the process of preparing the display panel after removing the sacrificial layer, which will not be repeated herein.

Embodiments of the present disclosure provide a display device including a display panel provided by embodiments of the present disclosure.

The display device provided by embodiments of the present disclosure is: a mobile phone, a tablet computer, a television, a monitor, a laptop computer, a digital photo frame, a navigator, and any other product or component having a display function. Other essential components of the display device should be understood by a person of ordinary skill in the art, and are not repeated herein, nor should they be used as a limitation of the present disclosure. The implementation of the display device can refer to the above embodiments of the display panel, and will not be repeated.

In summary, in the display panel and the preparation method therefor, and the display device, the flexible substrate in the bridge area is removed and the connecting lead passing through the bridge area is suspended, which can avoid the low stretch rate of the flexible substrate from affecting the overall stretching performance of the display panel. Moreover, a stretchable substrate is further provided on the side, away from the driving circuit layer, of the flexible substrate. In an stretched state of the stretchable substrate, the flexible substrate and each film layer on one side of the flexible substrate are transferred to the stretchable substrate, and afterwards, the stretchable substrate is restored to the unstretched state, which may reduce the size of the bridge area, so that at least a portion of the connecting lead sinks on one side facing the flexible substrate or the connecting lead protrudes on one side away from the flexible substrate, that is, the connecting lead is in a bent state, thereby increasing the stretch rate of the display panel.

Although preferred embodiments of the present disclosure have been described, those skilled in the art may make additional changes and modifications to those embodiments once the basic inventive concepts are known. Therefore, the appended claims are intended to be construed to include the preferred embodiments as well as all changes and modifications that fall within the scope of the present disclosure.

Obviously, those skilled in the art may make various changes and variations to the embodiments of the present disclosure without departing from the spirit and scope of the embodiments of the present disclosure. Thus, if these modifications and variations of the embodiments of the present disclosure fall within the scope of the claims of the present disclosure and their technical equivalents, the present disclosure is also intended to encompass these modifications and variations.

What is claimed is:

1. A display panel, comprising:
a stretchable substrate, comprising: a plurality of island areas arranged in an array, a plurality of bridge areas, and blanking areas outside the island areas and the bridge areas; wherein each bridge area connects two adjacent island areas;
a flexible substrate on one side of the stretchable substrate, wherein the flexible substrate comprises: a hollow area corresponding to the bridge areas and the blanking areas; and
a driving circuit layer on one side away from the stretchable substrate, of the flexible substrate; wherein the driving circuit layer comprises: a plurality of drive units and a plurality of connecting leads; the drive units are located in the island areas, and the connecting leads pass through the bridge areas and extend to the island areas to be electrically connected with the drive units; and in an unstretched state of the stretchable substrate, at least a portion of each connecting lead sinks toward one side facing the flexible substrate or each connecting lead protrudes toward one side away from the flexible substrate.

2. The display panel according to claim 1, wherein each connecting lead comprises at least one protrusion on the side facing the flexible substrate and/or on the side away from the flexible substrate.

3. The display panel according to claim 2, wherein each connecting lead comprises a plurality of protrusions; and the plurality of protrusions are not oriented in exactly the same direction.

4. The display panel according to claim 2, wherein an extended profile of each protrusion comprises a plurality of sub-protrusions; and the plurality of sub-protrusions are oriented in the same direction.

5. The display panel according to claim 1, wherein a shape of an orthographic projection of the connecting leads on the bridge areas is curved.

6. The display panel according to claim 1, wherein each drive unit comprises: a thin film transistor;
the connecting leads are located on one side, away from the flexible substrate, of the thin film transistor;
the driving circuit layer further comprises: a first protective layer between the connecting leads and the thin film transistor, a second protective layer between the first protective layer and the connecting leads, and a third protective layer on one side, away from the flexible substrate, of the connecting leads;
the second protective layer and the third protective layer pass through the bridge areas and extend to the island areas;
an orthographic projection of the connecting leads on the flexible substrate falls within an orthographic projection of the second protective layer on the flexible substrate, and the orthographic projection of the connecting leads on the flexible substrate falls within an orthographic projection of the third protective layer on the flexible substrate; and
the third protective layer covers a surface on the side, away from the flexible substrate, of the connecting leads, and a side surface of the connecting leads.

7. The display panel according to claim 6, wherein in the bridge areas, the orthographic projection of the second protective layer on the flexible substrate approximately coincides with the orthographic projection of the third protective layer on the flexible substrate.

8. The display panel according to claim 6, wherein each connecting lead comprises: a first sub-layer, and a second sub-layer on one side, away from the flexible substrate, of the first sub-layer; and
in a direction perpendicular to the flexible substrate, a thickness of the second sub-layer is greater than a thickness of the first sub-layer.

9. The display panel according to claim 1, further comprising:
a plurality of micro-sized inorganic light emitting diode devices, which are located in the island areas and bound to the driving circuit layer on one side, away from the flexible substrate, of the driving circuit layer; and
a stretchable cover plate on one side away from the flexible substrate, of the micro-sized inorganic light emitting diode devices.

10. A method for preparing a display panel, comprising:
providing a first substrate; wherein the first substrate comprises: a plurality of island areas arranged in an array, a plurality of bridge areas, and blanking areas outside the island areas and the bridge areas; and each bridge area connects two adjacent the island areas;
forming a flexible substrate on one side of the first substrate;
forming a pattern of a driving circuit layer on one side away from the first substrate, of the flexible substrate, and patterning the flexible substrate to form hollow areas in the blanking areas and the bridge areas; wherein the driving circuit layer comprises: a plurality of drive units and a plurality of connecting leads; the drive units are located in the island areas, and the connecting leads pass through the bridge areas and extend to the island areas to be electrically connected with the drive units;
stripping the first substrate and transferring a structure formed on one side of the first substrate to a stretchable substrate that is stretched by applying a tension force; and
releasing the tension force on the stretchable substrate to cause the stretchable substrate to restore to an unstretched state; wherein in the unstretched state of the stretchable substrate, at least a portion of each connecting lead sinks toward one side facing the flexible substrate or each connecting lead protrudes on one side away from the flexible substrate.

11. The method according to claim 10, wherein the forming the pattern of the driving circuit layer on one side away from the first substrate, of the flexible substrate, and patterning the flexible substrate to form the hollow areas in the blanking areas and the bridge areas, comprises:
forming a pattern of a partial film layer comprised in the driving circuit layer on the side away from the first substrate, of the flexible substrate, and patterning the flexible substrate to form the hollow areas in the blanking areas and the bridge areas;
forming a sacrificial layer in an area corresponding to the hollow areas;
forming a pattern of the connecting leads on one side away from the first substrate, of the sacrificial layer; and
removing the sacrificial layer.

12. The method according to claim 10, wherein the forming the sacrificial layer in the area corresponding to the hollow areas, comprises:
forming a metal sacrificial layer in the area corresponding to the hollow areas by using an electroplating process;
wherein the removing the sacrificial layer, comprises:
removing the sacrificial layer by using a wet etching process.

13. The method according to claim 12, wherein the forming the metal sacrificial layer in the area corresponding to the hollow areas by using the electroplating process, comprises:
forming a seed layer covering the partial film layer and the hollow areas;
forming a strippable electroplating retaining wall covering the seed layer in an area outside the hollow areas;
powering on the seed layer to grow an electroplating layer in the hollow areas, and filling the area corresponding to the hollow areas to form the metal sacrificial layer;
removing the strippable electroplating retaining wall; and
removing the seed layer outside the hollow areas and thinning the metal sacrificial layer, to make a surface on one side away from the first substrate, of the metal sacrificial layer be in a plane approximately the same as a plane where a surface on one side away from the first substrate, of the partial film layer is.

14. The method according to claim 11, wherein the forming the sacrificial layer in the area corresponding to the hollow areas, comprises:
forming an organic sacrificial layer by filling the area corresponding to the hollow areas with an organic material;
wherein the removing the sacrificial layer, comprises:
removing the organic sacrificial layer by using a stripping process with a stripping solution.

15. The method according to claim 11, wherein, after forming the sacrificial layer in the area corresponding to the hollow areas, and before forming the pattern of the connecting lead on one side away from the first substrate, of the sacrificial layer, the method further comprises:
forming a plurality of spacer structures on the side away from the first substrate, of the sacrificial layer; wherein the plurality of spacer structures are arranged at intervals in an arrangement direction of two adjacent island areas; and a surface on one side away from the first substrate, of the spacer structures is curved;
wherein while removing the sacrificial layer, the method further comprises:
removing the spacer structures.

16. The method according to claim 11, wherein the forming the pattern of the partial film layer comprised in the driving circuit layer on the side away from the first substrate, of the flexible substrate, and patterning the flexible substrate to form the hollow areas in the blanking areas and the bridge areas, comprises:
forming a pattern of film layers of a thin film transistor on the side away from the first substrate, of the flexible substrate; wherein the pattern of the film layers of the thin film transistor does not overlap with the blanking areas and the bridge areas;
forming a pattern of a first protective layer on one side away from the first substrate, of the film layers of the thin film transistor; wherein the pattern of the first protective layer does not overlap with the blanking areas and the bridge areas; and
patterning the flexible substrate by using the pattern of the first protective layer as a mask, to form the hollow areas in the blanking areas and the bridge areas;
wherein before forming the pattern of the connecting leads on the side away from the first substrate, of the sacrificial layer, the method further comprises:
forming a pattern of a second protective layer on the side away from the first substrate, of the sacrificial layer; wherein the second protective layer passes through the bridge areas and extend to the island areas;
wherein after the forming the pattern of the connecting lead on the side away from the first substrate, of the sacrificial layer, the method further comprises:
forming a pattern of a third protective layer on one side away from the sacrificial layer, of the connecting leads; wherein the third protective layer passes through the bridge areas and extends to the island areas.

17. The method according to claim 16, wherein after removing the sacrificial layer and before stripping the first substrate, the method further comprises:
binding a micro-sized inorganic light emitting diode device on one side away from the flexible substrate, of the driving circuit layer; and
affixing a protective film on one side away from the flexible substrate, of the micro-sized inorganic light emitting diode device;
wherein after releasing the tension force on the stretchable substrate to cause the stretchable substrate returns to restore to the unstretched state, the method further comprises:
removing the protective film.

18. The method according to claim 17, wherein after removing the protective film, the method further comprises:
affixing a stretchable cover on one side away from the flexible substrate, of the micro-sized inorganic light emitting diode device.

19. A display device, comprising the display panel according to claim 1.
